(19) United States
(12) Patent Application Publication
(10) Pub. No.: US 2026/0112857 A1
(43) Pub. Date: Apr. 23, 2026

(54) METHOD OF MANUFACTURING SEMICONDUCTOR DEVICE

(71) Applicant: Mitsubishi Electric Corporation, Tokyo (JP)

(72) Inventors: Yu FUKUNAGA, Tokyo (JP); Hiroaki MAEDA, Fukuoka (JP)

(73) Assignee: Mitsubishi Electric Corporation, Tokyo (JP)

(21) Appl. No.: 19/307,728

(22) Filed: Aug. 22, 2025

(30) Foreign Application Priority Data
Oct. 18, 2024 (JP) 2024-183926

(51) Int. Cl. H01R 43/24; H01R 9/24

(52) U.S. Cl. CPC H01R 43/24; H01R 9/24

(57) ABSTRACT

A case of a semiconductor device has a plurality of electrode terminal blocks each including a group of electrode terminals. In a step of forming the case, a connected electrode terminal block in which the plurality of electrode terminal blocks are connected via a connecting bar is prepared. The connected electrode terminal block is disposed in a mold, and the mold is filled with a resin to insert mold the case. The connecting bar is then removed from the connected electrode terminal block to divide the connected electrode terminal block into the electrode terminals.

### BACKGROUND OF THE INVENTION

### Field of the Invention

The present disclosure relates to a method of manufacturing a semiconductor device.

### Description of the Background Art

Insert molding is known as a method of forming a case for use in a semiconductor device for power control and the like, for example. In insert molding, electrode terminals are arranged in a mold, and the mold is filled with a resin to form a case into which the electrode terminals have been inserted. For example, Japanese Patent Application Laid-Open No. 2022-82033 discloses, as a case formed by insert molding, a case having a plurality of blocks (hereinafter referred to as “electrode terminal blocks”) each including a group of electrode terminals.

The electrode terminals are generally manually arranged in the mold, so that there are concerns about misalignment of the electrode terminals, a failure to dispose any of the electrode terminals, and the like. The concerns grow especially in formation of the case having the plurality of electrode terminal blocks because many electrode terminals are required to be arranged at close intervals.

### SUMMARY

It is an object of the present disclosure to prevent misalignment of electrode terminals and a failure to dispose any of the electrode terminals in insert molding of a case having a plurality of electrode terminal blocks.

A method of manufacturing a semiconductor device according to the present disclosure is a method of manufacturing a semiconductor device including a case having a plurality of electrode terminal blocks each including a group of electrode terminals and includes: steps (a) to (c) below. The step (a) is a step of preparing a connected electrode terminal block in which the plurality of electrode terminal blocks are connected via a connecting bar. The step (b) is a step of disposing the connected electrode terminal block in a mold and filling the mold with a resin to insert mold the case. The step (c) is a step of removing, after the step (b), the connecting bar from the connected electrode terminal block to divide the connected electrode terminal block into the electrode terminals.

According to the present disclosure, misalignment of the electrode terminals and a failure to dispose any of the electrode terminals can be prevented in insert molding of the case having the plurality of electrode terminal blocks.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram illustrating a configuration of a case of a semiconductor device according to Embodiment 1;

FIG. 2 is a diagram illustrating a configuration of a ladder connected electrode terminal according to Embodiment 1;

FIG. 3 is a diagram illustrating a configuration of connected electrode terminal blocks according to Embodiment 1;

FIG. 4 is a diagram illustrating the case immediately after insert molding;

FIG. 5 is a diagram illustrating the case immediately after insert molding;

FIG. 6 is a diagram illustrating a configuration of a ladder connected electrode terminal according to Embodiment 2; and

FIG. 7 is a diagram illustrating a configuration of connected electrode terminal blocks according to Embodiment 2.

### DESCRIPTION OF THE PREFERRED EMBODIMENTS

### Embodiment 1

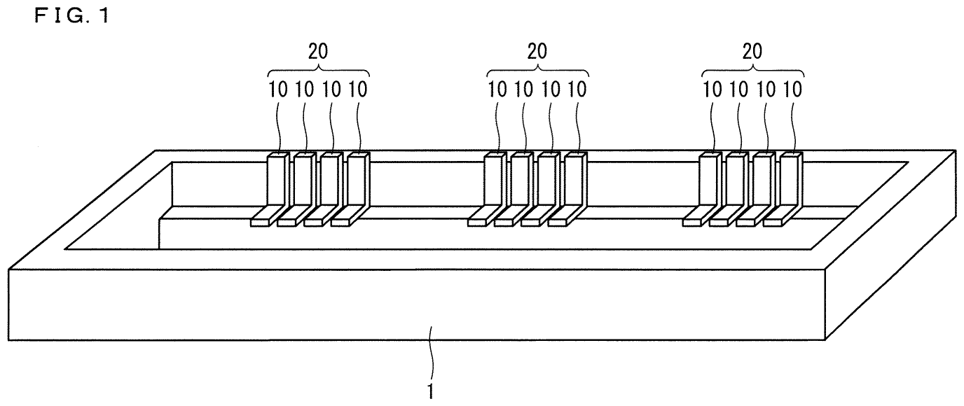

FIG. 1 is a diagram illustrating a configuration of a case 1 of a semiconductor device according to Embodiment 1. As illustrated in FIG. 1, the case 1 has a plurality of electrode terminal blocks 20 each including a group of electrode terminals 10. In the present embodiment, an example in which three electrode terminal blocks 20 each including four electrode terminals 10 are arranged in the case 1 is shown. Arrangement and the number of the electrode terminals 10 and the electrode terminal blocks 20, however, are not limited to those in this example.

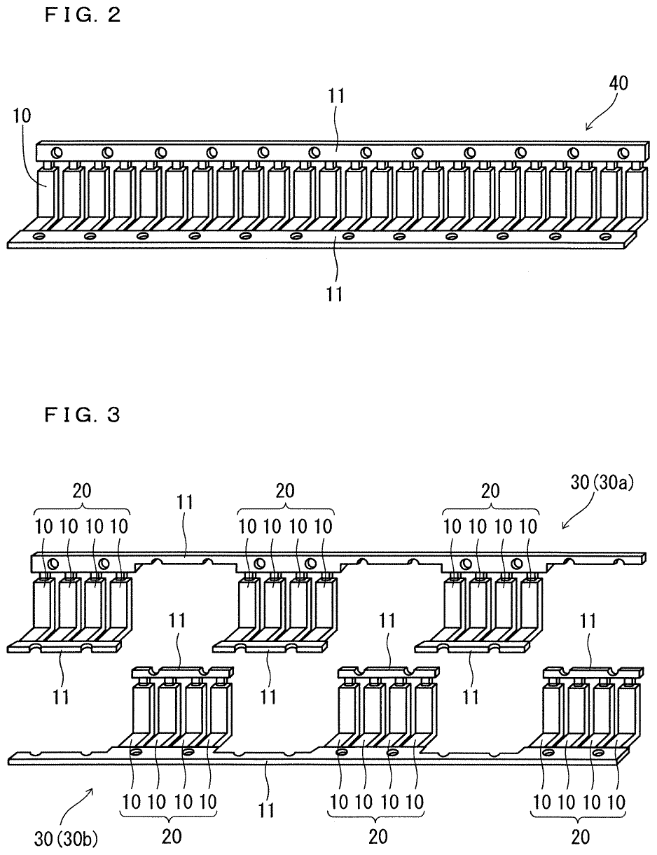

A method of manufacturing the semiconductor device according to Embodiment 1, in particular, a method of forming the case 1 will be described. First, as illustrated in FIG. 2, a ladder connected electrode terminal 40 in which a plurality of electrode terminals 10 are connected between two connecting bars 11 in a ladder configuration is prepared. That is to say, in the ladder connected electrode terminal 40, opposite ends of the plurality of electrode terminals 10 are connected by the respective connecting bars 11. In the ladder connected electrode terminal 40 in FIG. 2, the electrode terminals 10 for two cases 1 (i.e., for six electrode terminal blocks 20) are connected by the two connecting bars 11.

Next, as illustrated in FIG. 3, the ladder connected electrode terminal 40 is cut into two portions to form two connected electrode terminal blocks 30 in each of which electrode terminal blocks 20 for one case 1 are connected via a connecting bar 11. One and the other one of the two connected electrode terminal blocks 30 cut out of the ladder connected electrode terminal 40 are herein respectively defined as a “connected electrode terminal block 30a” and a “connected electrode terminal block 30b”. As can be seen from FIG. 3, the electrode terminal blocks 20 belonging to the connected electrode terminal block 30a and the electrode terminal blocks 20 belonging to the connected electrode terminal block 30b are arranged complementarily in the ladder connected electrode terminal 40. Due to this arrangement, the two connected electrode terminal blocks 30 can be obtained from the one ladder connected electrode terminal 40. This arrangement has an added benefit of allowing use of the electrode terminals 10 included in the ladder connected electrode terminal 40 without waste.

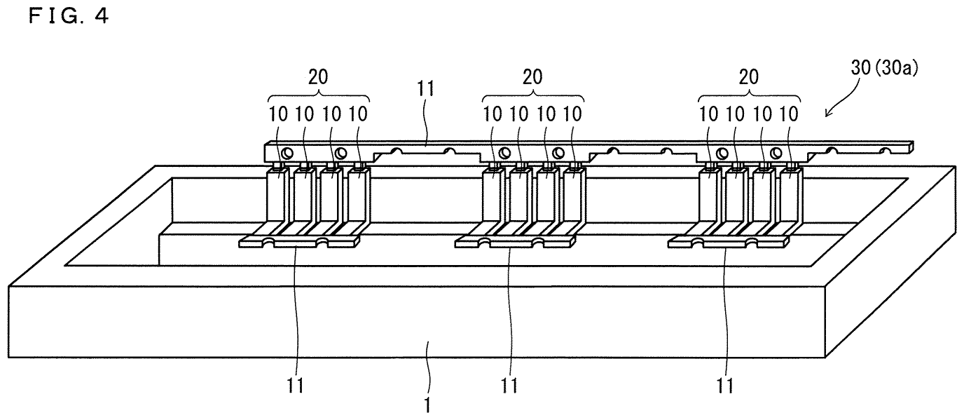

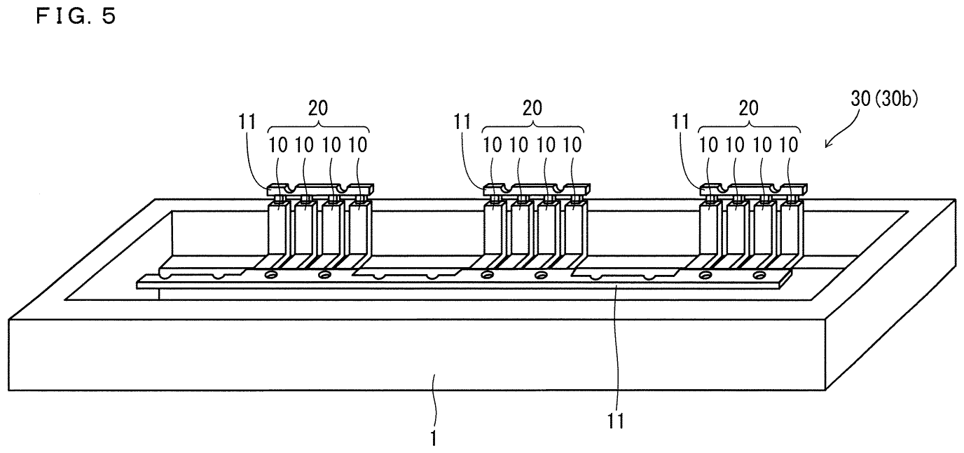

Next, each of the connected electrode terminal blocks 30 is disposed in a mold with the connecting bars 11 attached thereto. The mold is filled with a resin to insert mold the case 1. The case 1 immediately after insert molding is illustrated in each of FIGS. 4 and 5. FIG. 4 illustrates the case 1 into which the connected electrode terminal block 30a has been inserted, and FIG. 5 illustrates the case 1 into which the connected electrode terminal block 30b has been inserted.

The connecting bars 11 are then removed from each of the connected electrode terminal blocks 30 inserted into the case 1. Each of the connected electrode terminal blocks 30 is thereby divided into the electrode terminals 10 to complete the case 1 illustrated in FIG. 1.

Although not illustrated, semiconductor elements, a substrate to which the semiconductor elements are mounted, wiring, and the like are contained in the completed case 1 to manufacture the semiconductor device.

As described above, in the method of manufacturing the semiconductor device according to Embodiment 1, a step of arranging the electrode terminals 10 in the mold to insert mold the case 1 is performed by disposing each of the connected electrode terminal blocks 30 in the mold with the connecting bars 11 attached thereto. The electrode terminal blocks 20 for one case 1 are connected via the connecting bar 11 in each of the connected electrode terminal blocks 30, so that misalignment of the electrode terminals and a failure to dispose any of the electrode terminals are prevented. An effect of facilitating management of the number of electrode terminals 10 is also expected.

In the present embodiment, the ladder connected electrode terminal 40 includes the electrode terminals 10 for the two connected electrode terminal blocks 30, and the two connected electrode terminal blocks 30 are obtained from the one ladder connected electrode terminal 40. However, the number of electrode terminals 10 included in the ladder connected electrode terminal 40 may be increased to obtain three or more connected electrode terminal blocks 30 from the one ladder connected electrode terminal 40.

The ladder connected electrode terminal 40 has a uniform configuration in which the plurality of electrode terminals 10 are connected at regular intervals. The connected electrode terminal blocks 30 differing in number of electrode terminals 10 and arrangement of the electrode terminals 10 can thus be obtained from the same ladder connected electrode terminal 40 by changing a cutting position of each of the connecting bars 11.

### Embodiment 2

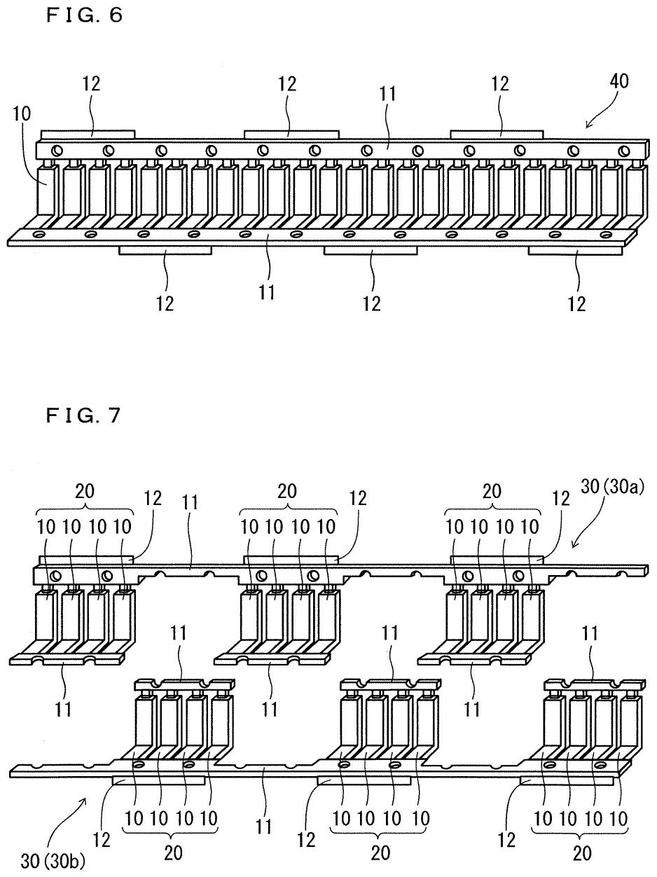

FIG. 6 is a diagram illustrating a configuration of a ladder connected electrode terminal 40 according to Embodiment 2, and FIG. 7 is a diagram illustrating two connected electrode terminal blocks 30 (connected electrode terminal blocks 30a and 30b) cut out of the ladder connected electrode terminal 40 in FIG. 6.

As illustrated in FIGS. 6 and 7, in Embodiment 2, connecting bars 11 of the ladder connected electrode terminal 40 each include marks 12 to allow electrode terminal blocks 20 to be distinguished from one another. While the marks 12 illustrated in FIGS. 6 and 7 are protrusions, the marks 12 may have any shapes.

The connecting bars 11 of the ladder connected electrode terminal 40 each include the marks 12 to define positions at which the connecting bars 11 are to be cut when the connected electrode terminal blocks 30 are cut out of the ladder connected electrode terminal 40 and to prevent cutting at a wrong position. An effect of preventing misalignment of the electrode terminals 10 and a failure to dispose any of the electrode terminals 10 is thus further improved.

Embodiments can freely be combined with each other and can be modified or omitted as appropriate.

### Appendices

Various aspects of the present disclosure will collectively be described below as appendices.

### Appendix 1

A method of manufacturing a semiconductor device including a case having a plurality of electrode terminal blocks each including a group of electrode terminals, the method comprising:
(a) preparing a connected electrode terminal block in which the plurality of electrode terminal blocks are connected via a connecting bar;
(b) disposing the connected electrode terminal block in a mold and filling the mold with a resin to insert mold the case; and
(c) after the step (b), removing the connecting bar from the connected electrode terminal block to divide the connected electrode terminal block into the electrode terminals.

### Appendix 2

The method of manufacturing the semiconductor device according to Appendix 1, wherein
the step (a) includes:
   preparing a ladder connected electrode terminal in which electrode terminals for at least two connected electrode terminal blocks are connected between two connecting bars in a ladder configuration; and
   cutting the ladder connected electrode terminal into the at least two connected electrode terminal blocks.

### Appendix 3

The method of manufacturing the semiconductor device according to Appendix 2, wherein
one or more of the electrode terminal blocks belonging to one of the at least two connected electrode terminal blocks cut out of the ladder connected electrode terminal and one or more of the electrode terminal blocks belonging to the other one of the at least two connected electrode terminal blocks are arranged complementarily in the ladder connected electrode terminal.

### Appendix 4

The method of manufacturing the semiconductor device according to Appendix 2 or 3, wherein
the connecting bars of the ladder connected electrode terminal each include marks to allow the electrode terminal blocks to be distinguished from one another.

While the invention has been shown and described in detail, the foregoing description is in all aspects illustrative and not restrictive. It is therefore understood that numerous modifications and variations can be devised without departing from the scope of the invention.

What is claimed is:

1. A method of manufacturing a semiconductor device including a case having a plurality of electrode terminal blocks each including a group of electrode terminals, the method comprising:
(a) preparing a connected electrode terminal block in which the plurality of electrode terminal blocks are connected via a connecting bar;
(b) disposing the connected electrode terminal block in a mold and filling the mold with a resin to insert mold the case; and
(c) after the step (b), removing the connecting bar from the connected electrode terminal block to divide the connected electrode terminal block into the electrode terminals.

2. The method of manufacturing the semiconductor device according to claim 1, wherein
the step (a) includes:
preparing a ladder connected electrode terminal in which electrode terminals for at least two connected electrode terminal blocks are connected between two connecting bars in a ladder configuration; and
cutting the ladder connected electrode terminal into the at least two connected electrode terminal blocks.

3. The method of manufacturing the semiconductor device according to claim 2, wherein
one or more of the electrode terminal blocks belonging to one of the at least two connected electrode terminal blocks cut out of the ladder connected electrode terminal and one or more of the electrode terminal blocks belonging to the other one of the at least two connected electrode terminal blocks are arranged complementarily in the ladder connected electrode terminal.

4. The method of manufacturing the semiconductor device according to claim 2, wherein
the connecting bars of the ladder connected electrode terminal each include marks to allow the electrode terminal blocks to be distinguished from one another.

5. The method of manufacturing the semiconductor device according to claim 3, wherein
the connecting bars of the ladder connected electrode terminal each include marks to allow the electrode terminal blocks to be distinguished from one another.
